(19) United States
(12) Patent Application Publication
(10) Pub. No.: US 2007/0235847 A1
(43) Pub. Date: Oct. 11, 2007

(54) Method of making a substrate having thermally conductive structures and resulting devices

(76) Inventors: Shriram Ramanathan, Portland, OR (US); Sanjiv Sinha, Portland, OR (US); Patrick R. Morrow, Portland, OR (US); Mark A. Trautman, Aloha, OR (US)

Correspondence Address: INTEL CORPORATION;c/o INTELLEVATE, LLC, P.O. BOX 52050, MINNEAPOLIS, MN, 55402, US

(21) Appl. No.: 11/230,032

(22) Filed: Sep. 19, 2005

(51) Int. Cl. H01L 23/02

(52) U.S. Cl. 257/678

(57) ABSTRACT

Embodiments of a method of fabricating a substrate including thermally conductive structures, as well as devices made from such a substrate, are disclosed. Each thermally conductive structure includes a via and a number of carbon nanotubes formed within the via. An active circuit element disposed on the substrate may at least partially overlie (or underlie) a location of one of the vias. The substrate may be cut into a number of separate die, each die including some of the thermally conductive structures. Other embodiments are described and claimed.

### FIELD OF THE INVENTION

The disclosed embodiments relate generally to the fabrication of integrated circuit devices and, more particularly, to the fabrication of substrates having thermally conductive structures.

### BACKGROUND OF THE INVENTION

As the performance of integrated circuit devices improves with each design generation, greater demands are placed upon the cooling solution. High performance integrated circuit devices, including multi-core architectures, may require thermal solutions that reduce not only the steady-state temperature but also the transient thermal response. For example, in a multi-core die, a core-hopping strategy may be employed to dynamically manage the die temperature; however, such a core-hopping approach may require a fast thermal response in the temporal domain. Improving the transient thermal response of an integrated circuit die may require a die having enhanced thermal conductivity and/or a thermal solution that is in closer proximity to the active circuitry.

### BRIEF DESCRIPTION OF THE DRAWINGS

FIG. 1 is a block diagram illustrating an embodiment of a method of making a substrate having thermally conductive structures.

FIGS. 2A-2J are schematic diagrams illustrating embodiments of the method shown in FIG. 1.

FIGS. 3A-3B are schematic diagrams illustrating embodiments of the method shown in FIG. 1.

FIG. 4A is a schematic diagram illustrating an embodiment of the method shown in FIG. 1.

FIG. 4B is a schematic diagram illustrating an embodiment of the method shown in FIG. 1.

FIG. 5 is a block diagram illustrating another embodiment of a method of making a substrate having thermally conductive structures.

FIGS. 6A-6C are schematic diagrams illustrating embodiments of the method shown in FIG. 5.

FIG. 7 is a schematic diagram illustrating an embodiment of a method of growing carbon nanotubes.

FIGS. 8A-8E are schematic diagrams illustrating embodiments of the method shown in FIG. 7.

FIG. 9 is a schematic diagram illustrating an embodiment of a wafer which may be formed according to the disclosed embodiments.

FIG. 10 is a schematic diagram illustrating an embodiment of a computer system, which may include a component formed according to the disclosed embodiments.

### DETAILED DESCRIPTION OF THE INVENTION

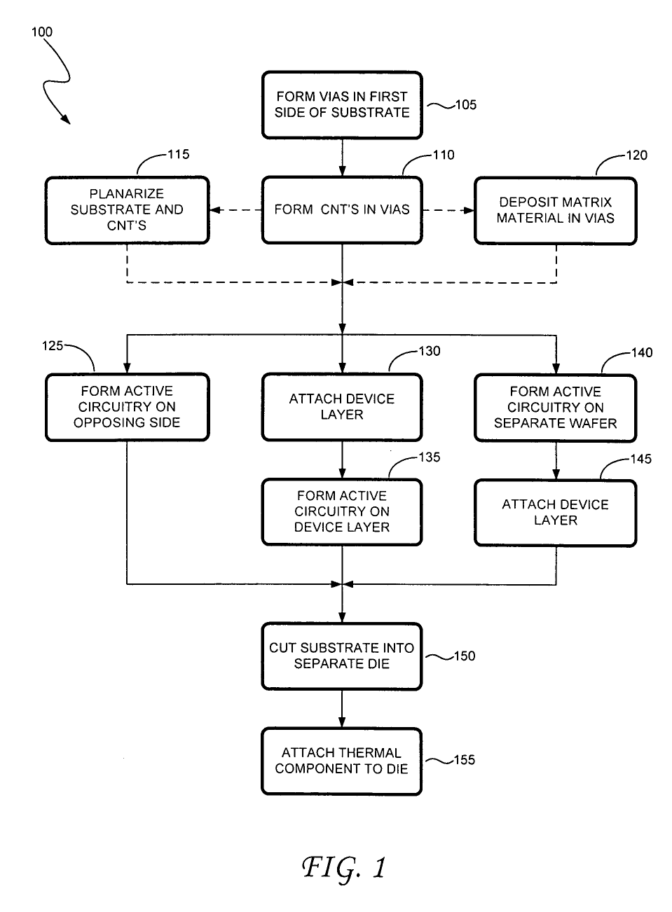

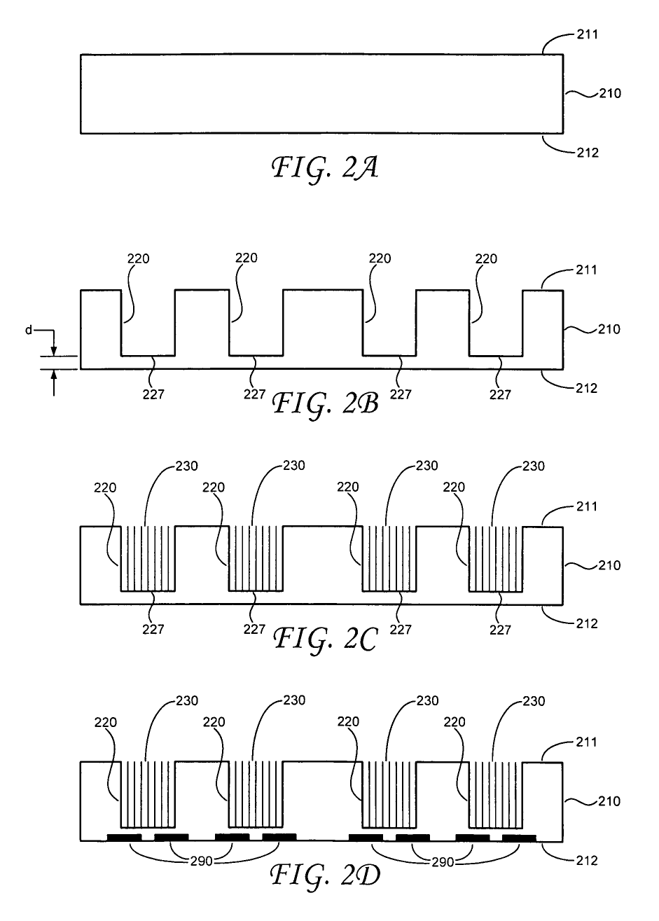

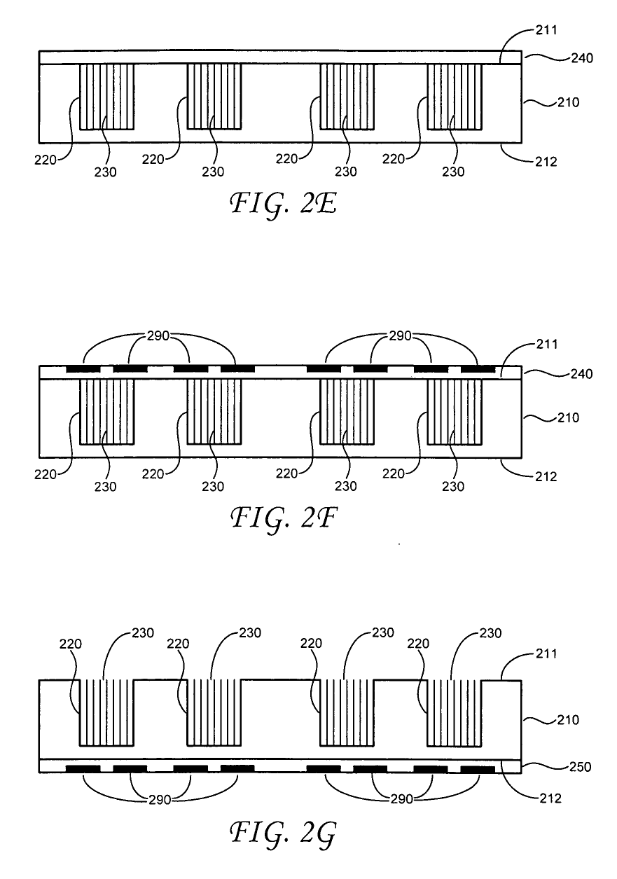

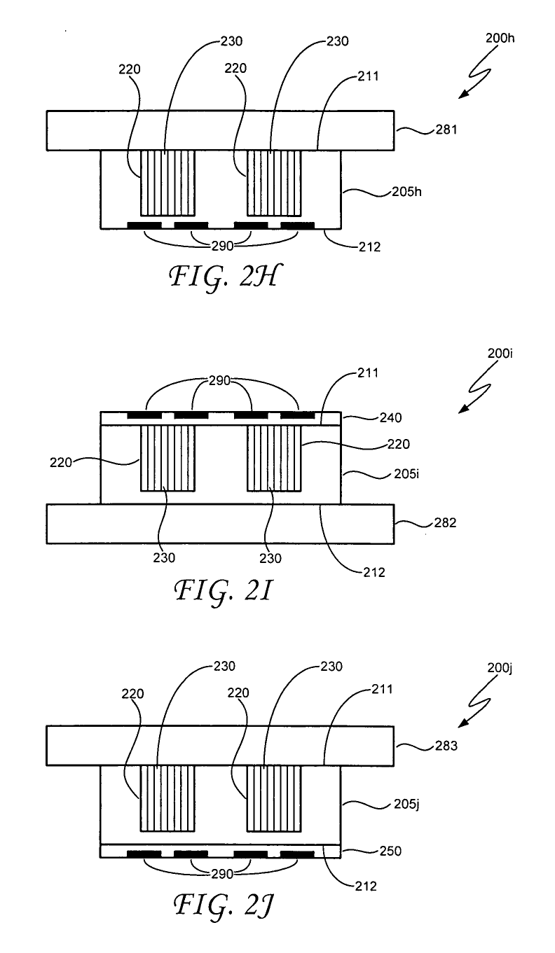

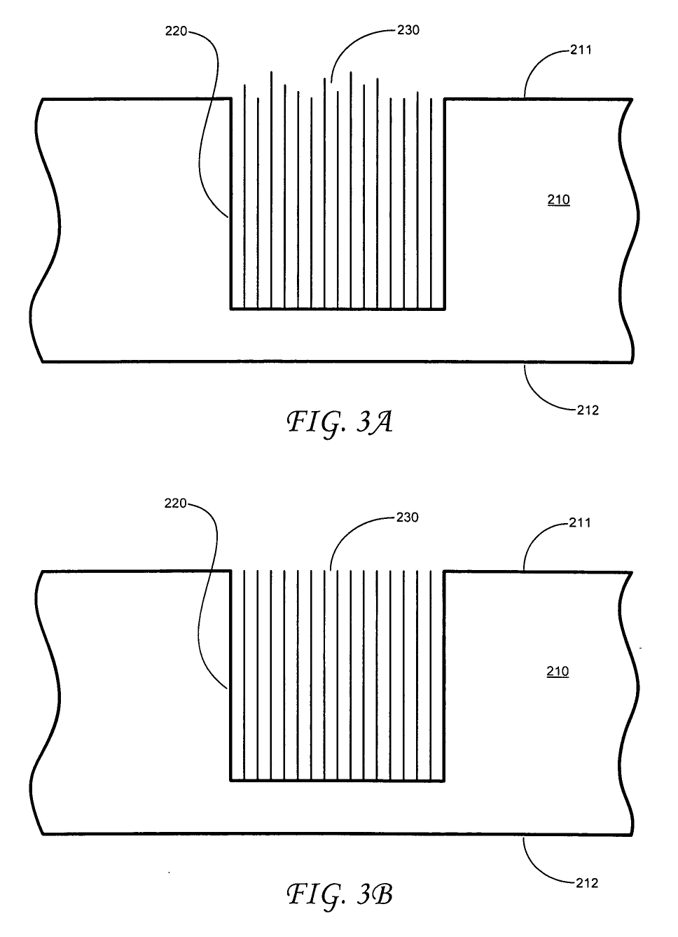

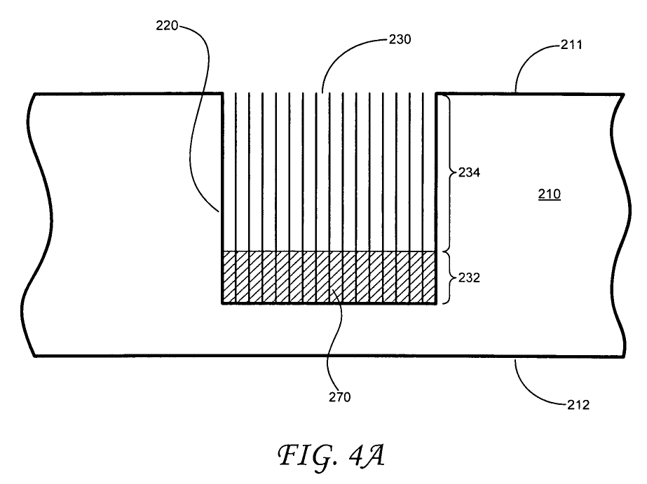

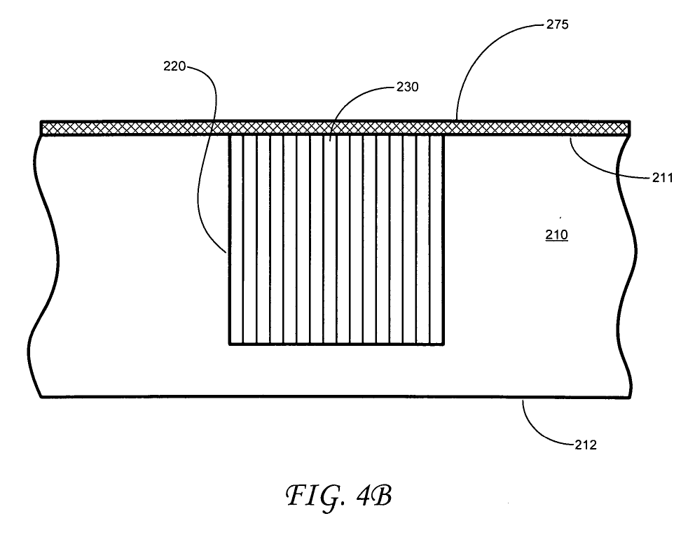

Turning now to FIG. 1, illustrated is an embodiment of a method 100 of making a substrate having thermally conductive structures. Embodiments of the method 100 shown in FIG. 1 are further illustrated in the schematic diagrams of FIGS. 2A through 2J, as well as FIGS. 3A-3B and FIGS. 4A-4B, and reference should be made to these figures as called out in the text below.

Referring to block 105 in FIG. 1, a number of vias are formed in the first side of a substrate. This is illustrated in FIGS. 2A and 2B. With reference first to FIG. 2A, a substrate 210 is shown. The substrate 210 may be viewed as having a first side 211 and an opposing second side 212. It should be understood, however, that the labels “first side” and “second side” are arbitrary and, further, that the various surfaces of the substrate 210 may be referenced by any suitable convention. In one embodiment, the substrate 210 comprises a semiconductor wafer upon which integrated circuitry for a number of die has been (or is to be) formed. The semiconductor wafer may comprise any suitable material, such as silicon, silicon-on-insulator (SOI), gallium arsenide (GaAs), or other material or combination of materials. According to one embodiment, the substrate has a thickness up to 800 μm.

With reference now to FIG. 2B, a number of vias 220 have been formed on the first side 211 of the substrate 210. In one embodiment, each of the vias 220 extends from the substrate's first side 211 to a base or bottom 227. The vias may be distributed across the first side 211 according to any desired pattern, and the vias may be uniformly or non-uniformly distributed. In one embodiment, the vias are formed at locations that are directly under regions of heat production in the substrate 210 (e.g., at locations corresponding to processor cores or other circuitry that has been or is to be formed on the substrate 210). According to one embodiment, the distance (d) between the base 227 of each vias 220 and the substrate's second side 212 comprises a distance sufficient to prevent interference with active circuitry (e.g., the n- or p-wells of a transistor) located at the second side 212. In one embodiment, the distance (d) comprises a distance up to 1 μm. The vias 220 may be formed using any suitable process, including etching (e.g., plasma etching), laser drilling, or a mechanical drilling process.

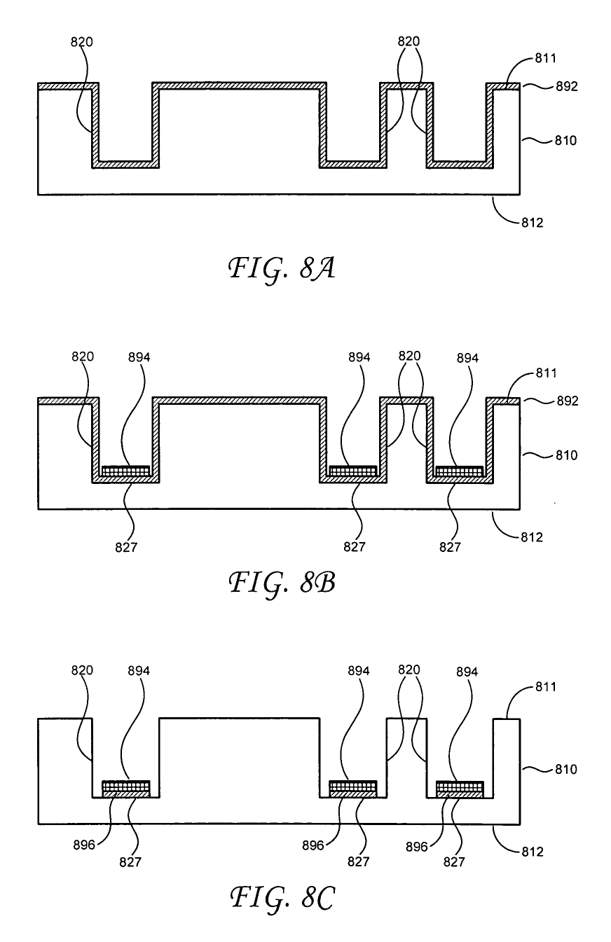

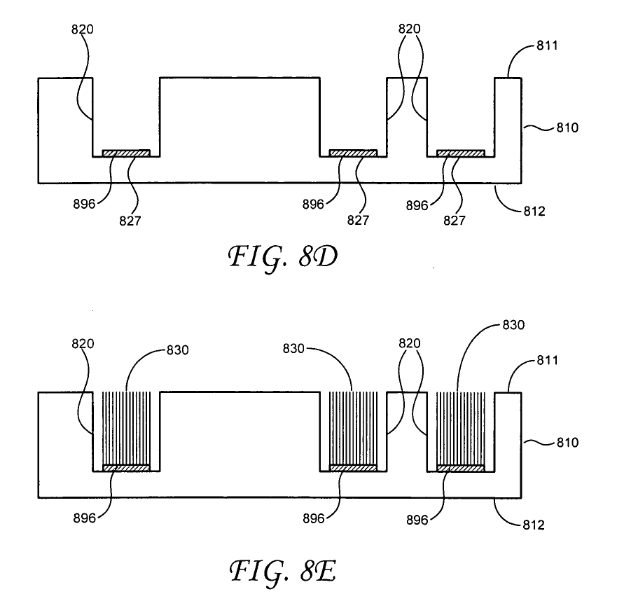

Referring to block 110 in FIG. 1, a number of carbon nanotubes are formed in each of the vias. This is illustrated in FIG. 2C, which shows a number of carbon nanotubes 230 formed within each of the vias 220. The carbon nanotubes may be formed using any suitable process, and the carbon nanotubes may be single-walled or multi-walled. One embodiment of a method of forming carbon nanotubes is described in FIGS. 7 through 8E and the accompanying text below. In one embodiment, the carbon nanotubes extend from approximately the base 227 of each via (although, as described below, one or more layers of a catalyst may be deposited at the base of the vias) to the substrate's first surface 211 (although, as described below, the carbon nanotubes in a given via may not be of precisely the same length).

A carbon nanotube (or “CNT”) is generally cylindrical in shape and may be single-walled or multi-walled, as noted above. A single-walled carbon nanotube may be grown to a length up to 1 cm and a diameter down to 1 nm, whereas a multi-walled carbon nanotube may be grown to a length up to 1 cm and a diameter down to 10 nm. It should, however, be understood that these are examples of the sizes to which carbon nanotubes can be formed, and that the actual sizes of the carbon nanotubes that are formed can vary with the process by which they are formed. Carbon nanotubes may be characterized by high mechanical strength, good chemical stability, and high thermal conductivity. For example, aligned bundles of single-walled carbon nanotubes may have a thermal conductivity of between approximately 240 W/mK and 3,000 W/mK at 100 degrees Celsius (as compared to, for example, silicon, which has a thermal conductivity of 117 W/mK at 100 degrees Celsius).

According to one embodiment, active circuitry is then formed on the opposing side of the substrate, as set forth in block 125. This is illustrated in FIG. 2D, which shows circuitry 290 disposed on the second side 212 of substrate 210. Circuitry 290 may comprise a collection of circuit elements, including transistors, capacitors, resistors, diodes, inductors, etc. According to one embodiment, at least some of the circuit elements 290 overly (or underlie) a portion of at least one of the vias 220 (and the bundle of carbon nanotubes 230 within that via).

As noted above, carbon nanotubes may exhibit greater thermal conductivity in comparison to the material (e.g., silicon) of substrate 210. Thus, the vias 220 with carbon nanotubes 230 provide paths through the substrate 210 having greater thermal conductivity. In addition, because the carbon nanotubes 230 extend to the base 227 of each via 220, the above-described thermally conductive paths are in relatively close proximity to the active circuitry 290 (in comparison to, for example, a typical heat spreader, which would be attached to the substrate's first side 211). Also, due to the enhanced thermal conductivity and the close proximity of the thermal solution to the heat producing circuitry, it is believed that the above-described thermally conductive paths will exhibit a fast thermal response in the time domain as well.

According to a second embodiment, after formation of the vias, a device layer is attached to the substrate, as set forth in block 130. This is illustrated in FIG. 2E, which shows a device layer 240 that has been attached to the first side 211 of substrate 210. In another embodiment, the device layer 240 is attached to the substrate's second side 212. The device layer 240 may comprise any suitable material upon which circuitry may be formed. In one embodiment, the device layer comprises silicon; however, it should be understood that device layer 240 may comprise any other suitable material or combination of materials (e.g., SOI, GaAs, etc.). According to one embodiment, the device layer 240 has a thickness up to 10 μm. The device layer 240 may be attached to substrate 210 using any suitable process. In one embodiment, the device layer 240 and substrate 210 are placed in contact under compression and elevated temperature for a time sufficient to form a diffusion bond between these two substrates.

In one embodiment, after attachment of the device layer, circuitry is formed on the device layer, as set forth in block 135. This is illustrated in FIG. 2F, which shows circuitry 290 that has been formed on device layer 240. Circuitry 290 may include a collection of circuit elements, including transistors, capacitors, resistors, diodes, inductors, etc. According to one embodiment, at least some of the circuit elements 290 overly (or underlie) a portion of at least one of the vias 220 (and the bundle of carbon nanotubes 230 within that via) in substrate 210.

According to a third embodiment, active circuitry is first formed on a device layer, and then this device layer is attached to the substrate, as set forth in blocks 140 and 145. This is illustrated in FIG. 2G, which shows a device layer 250 having active circuitry 290 that has been attached to the second side 212 of substrate 210. In another embodiment, the device layer 250 with active circuitry 290 is attached to the substrate's first surface 211.

In summary, as set forth in blocks 130-145 and FIGS. 2E-2G, a separate device layer may be attached to either side (211 or 212) of substrate 210. Active circuitry may be formed on this separate device layer either prior to attachment to substrate 210 or after attachment to this substrate. Also, as noted above, in another embodiment, active circuitry may be directly formed on substrate 210 (see block 125 and FIG. 2D).

Also, although not shown in any of FIGS. 2D, 2F, or 2G, an interconnect structure may be formed over the second side 212 of substrate 210 or over the active circuitry of device layer 240. This interconnect structure may include a number of levels of metallization, each level of metallization comprising a layer of dielectric material in which a number of conductors (e.g., traces) has been formed. The conductors in any given level of metallization are separated from the conductors of adjacent levels by the dielectric material, and the conductors of adjacent levels are electrically interconnected by conductive vias extending between these levels. The conductors and vias may comprise any suitable conductive material, such as copper, aluminum, gold, silver, or alloys of these and other metals. The dielectric material may comprise any suitable dielectric or insulating material, such as silicon dioxide (SiO₂), SiOF, carbon-doped oxide (CDO), a glass, or a polymer material.

Referring now to block 150 in FIG. 1, irrespective of the manner in which active circuitry is provided, the substrate may be cut into separate die, and a thermal component may be attached to each die, as shown in block 155. This is illustrated, by way of example, in each of FIGS. 2H through 2J. Referring first to FIG. 2H, a device 200h is shown. The device 200h includes a die 205h that has been cut from the substrate 210 of FIG. 2D, and a thermal component 281 has been attached to the first side 211 of the die 205h. With reference to FIG. 2I, a device 200i is illustrated. The device 200i includes a die 205i that has been cut from the substrate 210 of FIG. 2F, and a thermal component 282 has been attached to the second side 212 of the die 205i. Turning now to FIG. 2J, a device 200j is shown. The device 200j includes a die 205j that has been cut from the substrate 210 of FIG. 2G, and a thermal component 283 has bee attached to the first side 211 of die 205j.

In the embodiments of FIGS. 2H-2J, each of the thermal components 281, 282, 283 may comprise any suitable type of thermal solution and/or device. For example, the thermal components 281, 282, 283 may each comprise a heat spreader, a heat sink, and/or a heat exchanger. Furthermore, the thermal components 281, 282, 283 may employ any suitable cooling mode or combination of cooling modes, including conduction (e.g., as may be performed by a heat spreader), convection to the ambient environment (e.g., as may be performed by a multi-fin heat sink), and fluid cooling (e.g., as may be performed by a micro-channel heat exchanger or cold plate). Also, in one embodiment, a layer of a thermal interface material (e.g., a solder) may be disposed between the thermal component and its mating die (in one embodiment, as described below, a capping layer disposed over the substrate and carbon nanotubes may function as a layer of thermal interface material). In addition, a thermal component may be secured to the die by any suitable method, including diffusion bonding, adhesive bonding, or solder reflow (e.g., where a solder thermal interface material is utilized).

Turning now to FIG. 3A, the formation of carbon nanotubes 230 (e.g., growth by chemical vapor deposition) may result in nanotubes of non-uniform height, as illustrated in this figure. In some embodiments, it may be desirable to minimize this non-uniformity to facilitate bonding of a device layer or a thermal component to first side 211 of the substrate 210. Thus, according to one embodiment, the first side 211 of substrate 210 is planarized, as set forth in block 115. This planarization process may planarize the first side 211 of substrate 210 and, at the same time, remove the upper tip of at least some of the carbon nanotubes 230, such that the nanotubes are of substantially uniform height, as illustrated in FIG. 3B. Any suitable process may be employed to planarize the substrate 2 10 and carbon nanotubes 230, such as, for example, chemical-mechanical polishing (or CMP).

In another alternative embodiment, as set forth in block 120 of FIG. 1, a matrix material is deposited in the vias. This is illustrated in FIG. 4A, where a matrix material 270 has been deposited within the vias 220 and around the carbon nanotubes 230. The matrix material 270 may provide mechanical support for the carbon nanotubes 230. Matrix material 270 may comprise any material (or combination of materials) that can provide mechanical support for the nanotubes 230, including oxides and other insulating materials. Further, the matrix material 270 may be deposited by any suitable process, such as chemical vapor deposition, atomic layer deposition, etc. Also, the matrix material 270 may fill the vias 220 to any desired depth, and in one embodiment a lower portion 232 of the carbon nanotubes 230 is supported by the matrix material 270, whereas an upper portion 234 of the nanotubes is unsupported by the matrix material. In one embodiment, the lower portion 232 of the nanotubes that is supported by matrix material 270 is less than the upper portion 234.

According to a further alternative embodiment (not shown in FIG. 1), a capping layer is deposited over the substrate and carbon nanotubes. This is illustrated in FIG. 4B, which shows a capping layer 275 that has been deposited over the first side 211 of substrate 210 and over the ends of the carbon nanotubes 230. The capping layer 275 may comprise any suitable thermally conductive material or combination of materials, such as, for example, copper, copper alloys, solders, etc. In one embodiment, the capping layer 275 provides a surface for the attachment of a thermal component (e.g., after die singulation), such as a heat spreader. In another embodiment, no planarization is performed, and the capping layer 275 cover the ends of the carbon nanotubes 230 (which have been grown to non-uniform lengths). In a further embodiment, in addition to capping layer 275, a matrix material is also deposited in the vias 220 (e.g., see FIG. 4A and the accompanying text above).

In the embodiments of FIGS. 1 through 2G, the formation of active circuitry 290 occurred after—or separate from (e.g., on a separate device layer 240)—the formation of carbon nanotubes 230. Formation of the circuitry after carbon nanotube growth may be desired where the temperature at which nanotube growth takes place is sufficiently high to damage any previously formed circuitry. However, in other embodiments, active circuitry may be formed prior to the growth of carbon nanotubes. For example, should a lower temperature nanotube growth process be developed and/or should active circuitry capable of withstanding higher post-processing temperatures be developed, nanotube growth may take place after circuit formation.

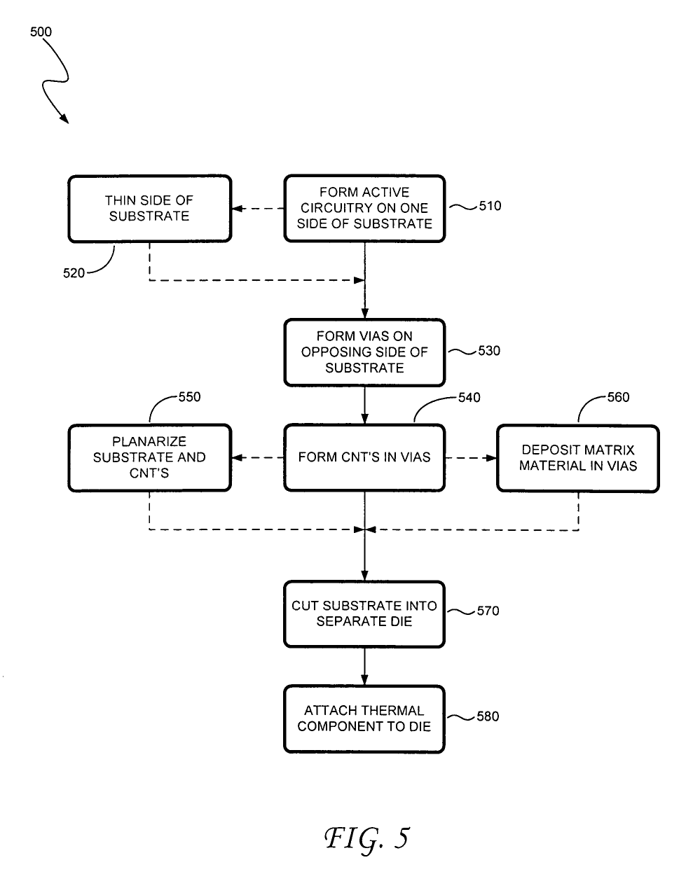

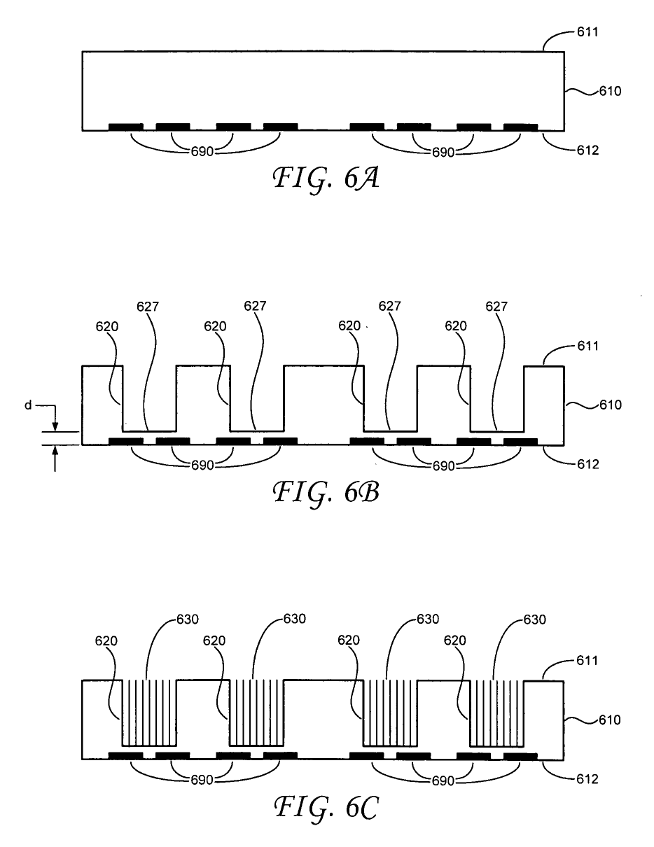

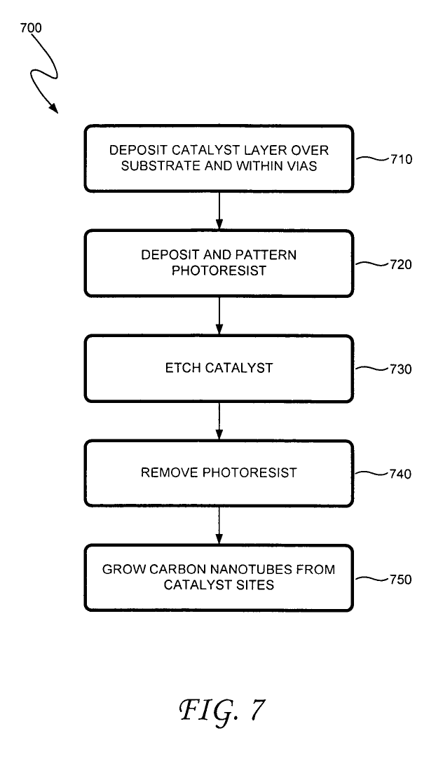

Illustrated in FIG. 5 is an embodiment of a method 500 of making a substrate having thermally conductive structures, where circuit formation takes place prior to carbon nanotube growth. Embodiments of the method 500 shown in FIG. 5 are further illustrated in the schematic diagrams of FIGS. 6A through 6C, and reference should be made to these figures as called out in the text below.

Referring to block 510 in FIG. 5, active circuitry is formed on one side of a substrate. This is illustrated in FIG. 6A, which shows a substrate 610. The substrate 610 may be viewed as having a first side 611 and an opposing second side 612. It should be understood, however, that the labels “first side” and “second side” are arbitrary and, further, that the various sides of the substrate 610 may be referenced by any suitable convention (for example, often times the side of a wafer upon which integrated circuitry is formed is referred to as the “front side” whereas the opposing side is referred to as the “back side”). In one embodiment, the substrate 610 comprises a semiconductor wafer, and the semiconductor wafer may comprise any suitable material, such as silicon, silicon-on-insulator (SOI), gallium arsenide (GaAs), or other material or combination of materials. As is also shown in FIG. 6A, circuitry 690 has been formed on the second side 612 of substrate 610. Circuitry 690 may comprise a collection of circuit elements, including transistors, capacitors, resistors, diodes, inductors, etc.

A number of vias are then formed in the substrate, as set forth in block 530. This is illustrated in FIG. 6B, where a number of vias 620 have been formed on the first side 611 of the substrate 610. In one embodiment, each of the vias 620 extends from the substrate's first side 211 to a base or bottom 627. According to one embodiment, the distance (d) between the base 627 of each vias 620 and the substrate's second side 612 comprises a distance sufficient to prevent interference with the active circuitry 690 (e.g., the n- or p-wells of a transistor) located at the second side 612. In one embodiment, the distance (d) comprises a distance up to 1 μm. The vias 620 may be formed using any suitable process, including etching (e.g., plasma etching), laser drilling, or a mechanical drilling process.

Referring to block 540 in FIG. 5, a number of carbon nanotubes are formed in each of the vias. This is illustrated in FIG. 6C, which shows a number of carbon nanotubes 630 formed within each of the vias 620. The carbon nanotubes may be formed using any suitable process, and the carbon nanotubes may be single-walled or multi-walled. One embodiment of a method of forming carbon nanotubes is described in FIGS. 7 through 8E and the accompanying text below. In one embodiment, the carbon nanotubes extend from approximately the base 627 of each via (although, as described below, one or more layers of a catalyst may be deposited at the base of the vias) to the substrate's first surface 611 (although, as described above, the carbon nanotubes in a given via may not be of precisely the same length). Also, according to one embodiment, at least some of the circuit elements 690 overly (or underlie) a portion of at least one of the vias 620 and the bundle of carbon nanotubes 630 within that via.

In one alternative embodiment, prior to via formation and carbon nanotube growth, the front side 611 (e.g., the “back side”) of the substrate 610 is thinned, as set forth in block 520. For example, the substrate 610 may have an original thickness up to approximately 800 μm. According to one embodiment, this substrate is thinned to a final thickness of between 10 μm and 300 μm.

In another embodiment, after carbon nanotube growth, the substrate and nanotubes are planarized, as set forth in block 550. Planarization of the substrate and nanotubes is described in FIGS. 3A-3B and the accompanying text above. In a further embodiment, after nanotube growth, a matrix material is deposited in the vias and around the carbon nanotubes. Deposition of the matrix material is also described above in FIG. 4 and the accompanying text. In further embodiments, the substrate 610 is cut into a number of separate die, and each of these die may be attached to a thermal component, as set forth in blocks 570 and 580. Singulation of the substrate into separate die and the attachment of a thermal solution to a die is described above with respect to FIGS. 2H through 2J and the accompanying text.

Turning now to FIG. 7, illustrated is an embodiment of a method of forming carbon nanotubes. Embodiments of the method 700 shown in FIG. 7 are further illustrated in the schematic diagrams of FIGS. 8A through 8E, and reference should be made to these figures as called out in the text below.

With reference now to block 710 in FIG. 7, a layer of catalyst is deposited over a substrate and within a number of vias formed on the substrate. This is illustrated in FIG. 8A, which shows a substrate 810 having a first side 811 and an opposing second side 812. Substrate 810 may comprise any of the embodiments previously described. A number of vias 820 have been formed in the first side 811 of the substrate 810. Also, a layer of a catalyst material 892 has been deposited over the substrate first surface 811 and over the walls of vias 820. Catalyst material 892 comprises any material or combination of materials that can function as an initiation site for the growth of one or more carbon nanotubes (or otherwise encourage the growth of nanotubes). Potential catalysts include gold, nickel, iron, platinum, or palladium, as well as alloys of these and other metals. According to one embodiment, the catalyst comprises multiple layers of these or other metals (e.g., a stack up of separate nickel, gold, and iron layers overlying one another). In one embodiment, the catalyst layer (or layers) are deposited using any suitable blanket deposition technique (e.g., sputtering, chemical vapor deposition, etc.).

Referring to block 720, a photoresist is deposited and patterned. This is illustrated in FIG. 8B, where a layer of photoresist has been deposited and patterned, such that photoresist 894 remains at the base 827 of each via (overlying the catalyst 892 at the via base). The photoresist 894 may comprise any suitable photoresist material (e.g., either a positive or negative photoresist), and the photoresist may be deposited using any suitable process (e.g., spin coating).

As set forth in block 730, the catalyst is then etched. This is illustrated in FIG. 8C, where the catalyst layer 892 has been etched away (e.g., using either a dry etch or wet etch process, etc.), except those portions of the catalyst layer underlying the remaining photoresist 894. Thus, pads 896 of catalyst material remain under photoresist 894. Referring to block 740, the photoresist is then removed, which is illustrated in FIG. 8D, where catalyst pads 896 remain at the base 827 of each via 820. The catalyst 896 remaining at the bottom of each via can serve as an initiation site for the growth of one or more carbon nanotubes (e.g., a bundle of single-walled or multi-walled carbon nanotubes).

Turning now to block 750 in FIG. 7, carbon nanotubes are grown from the catalyst sites. This is illustrated in FIG. 8E, where a number of carbon nanotubes 830 have been grown from the catalyst 896 in each of the vias 820. Any suitable process may be employed to grow the carbon nanotubes 830. In one embodiment, the carbon nanotubes are grown using a chemical vapor deposition process. In a further embodiment, an electric field is applied during nanotube growth in order to align the nanotubes (e.g., in a direction normal to the substrate first surface 811). It should be understood, however, that the disclosed embodiments are not limited to formation of carbon nanotubes from a layer of catalyst or to the formation of nanotubes by chemical vapor deposition and, further, that alternative carbon nanotube growth or formation techniques may be employed (e.g., self-assembly techniques).

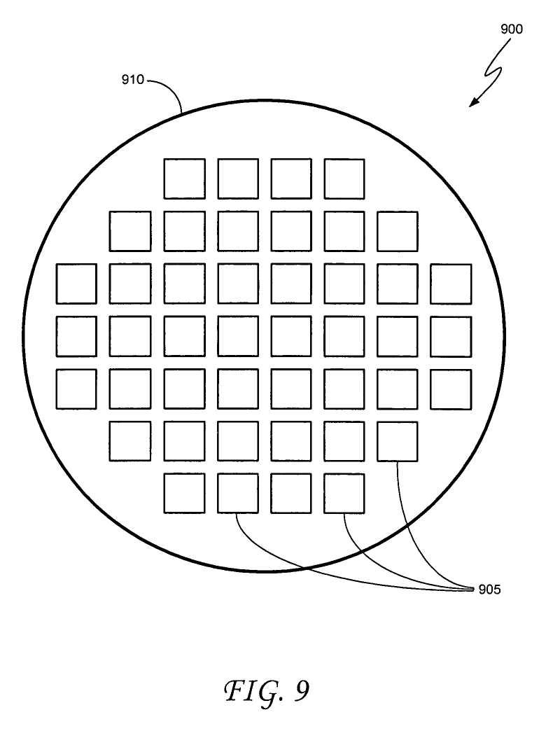

Although the substrate 210 shown in FIGS. 2A through 2G (as well as the substrate 610 of FIGS. 6A-6C and the substrate 810 of FIGS. 8A-8E) includes a limited number of vias 220 and circuit elements 290 for ease of illustration, it should be understood that the disclosed embodiments are typically performed at the wafer level and that such a wafer may include integrated circuitry for a number of die. This is further illustrated in FIG. 9 which shows a plan view of a wafer 900. Referring to this figure, the wafer 900 comprises a substrate 910 (e.g., Si, SOI, GaAs, etc.) upon which integrated circuitry for a number of die 905 has been formed, and wafer 900 is ultimately cut into these separate die 905. According to one embodiment, the substrate 910 includes a number of vias having bundles of carbon nanotubes formed therein, as described above. In practice, each of the die 905 may include hundreds of vias having nanotube bundles, and the wafer 900 as a whole may include thousands of these structures. Further, each die 905 may include hundreds of millions of circuit elements (e.g., transistors, etc.).

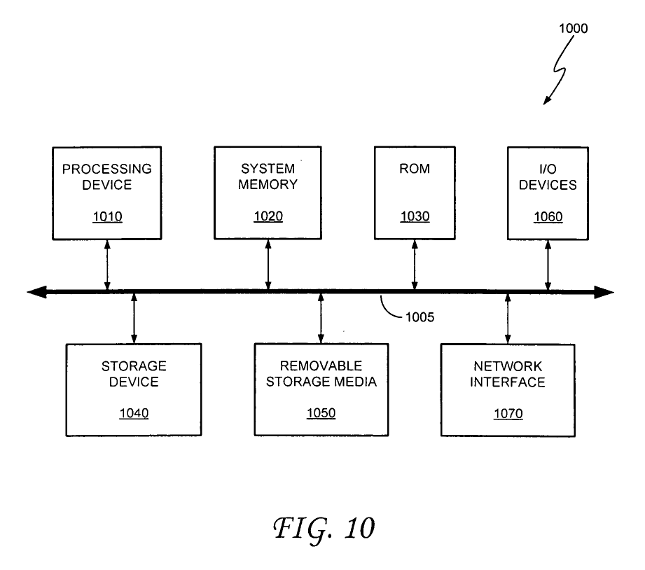

Referring to FIG. 10, illustrated is an embodiment of a computer system 1000. Computer system 1000 includes a bus 1005 to which various components are coupled. Bus 1005 is intended to represent a collection of one or more buses—e.g., a system bus, a Peripheral Component Interface (PCI) bus, a Small Computer System Interface (SCSI) bus, etc.—that interconnect the components of system 1000. Representation of these buses as a single bus 1005 is provided for ease of understanding, and it should be understood that the system 1000 is not so limited. Those of ordinary skill in the art will appreciate that the computer system 1000 may have any suitable bus architecture and may include any number and combination of buses.

Coupled with bus 1005 is a processing device (or devices) 1010. The processing device 1010 may comprise any suitable processing device or system, including a microprocessor, a network processor, an application specific integrated circuit (ASIC), or a field programmable gate array (FPGA), or similar device. It should be understood that, although FIG. 10 shows a single processing device 1010, the computer system 1000 may include two or more processing devices.

Computer system 1000 also includes system memory 1020 coupled with bus 1005, the system memory 1020 comprising, for example, any suitable type and number of memories, such as static random access memory (SRAM), dynamic random access memory (DRAM), synchronous DRAM (SDRAM), or double data rate DRAM (DDRDRAM). During operation of computer system 1000, an operating system and other applications may be resident in the system memory 1020.

The computer system 1000 may further include a read-only memory (ROM) 1030 coupled with the bus 1005. The ROM 1030 may store instructions for processing device 1010. The system 1000 may also include a storage device (or devices) 1040 coupled with the bus 1005. The storage device 1040 comprises any suitable non-volatile memory, such as, for example, a hard disk drive. The operating system and other programs may be stored in the storage device 1040. Further, a device 1050 for accessing removable storage media (e.g., a floppy disk drive or a CD ROM drive) may be coupled with bus 1005.

The computer system 1000 may also include one or more I/O (Input/Output) devices 1060 coupled with the bus 1005. Common input devices include keyboards, pointing devices such as a mouse, as well as other data entry devices, whereas common output devices include video displays, printing devices, and audio output devices. It will be appreciated that these are but a few examples of the types of I/O devices that may be coupled with the computer system 1000.

The computer system 1000 may further comprise a network interface 1070 coupled with bus 1005. The network interface 1070 comprises any suitable hardware, software, or combination of hardware and software that is capable of coupling the system 1000 with a network (e.g., a network interface card). The network interface 1070 may establish a link with the network (or networks) over any suitable medium—e.g., wireless, copper wire, fiber optic, or a combination thereof supporting the exchange of information via any suitable protocol—e.g., TCP/IP (Transmission Control Protocol/Internet Protocol), HTTP (Hyper-Text Transmission Protocol), as well as others.

It should be understood that the computer system 1000 illustrated in FIG. 10 is intended to represent an exemplary embodiment of such a system and, further, that this system may include many additional components, which have been omitted for clarity and ease of understanding. By way of example, the system 1000 may include a DMA (direct memory access) controller, a chip set associated with the processing device 1010, additional memory (e.g., a cache memory), as well as additional signal lines and buses. Also, it should be understood that the computer system 1000 may not include all of the components shown in FIG. 10. The computer system 1000 may comprise any type of computing device, such as a desktop computer, a laptop computer, a server, a hand-held computing device (e.g., a personal digital assistant, or PDA), a wireless communication device, an entertainment system, etc.

In one embodiment, the computer system 1000 includes a component constructed according to any of the embodiments disclosed above. For example, the processing device 1010 of system 1000 may include a die employing vias with carbon nanotube bundles as part of the thermal solution. However, it should be understood that other components of system 1000 (e.g., network interface 1070, etc.) may include a device formed according to any of the disclosed embodiments.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. A method comprising:
forming a number of vias on a first side of a substrate;
forming a number of carbon nanotubes within each of the vias; and
forming circuitry on a second opposing side of the substrate.

2. The method of claim 1, wherein the substrate comprises a wafer that is to be cut into a number of die, each die including some of the circuitry.

3. The method of claim 2, further comprising:
cutting the semiconductor wafer into the number of die; and
attaching a thermal component to the first side of at least one of the die.

4. The method of claim 1, wherein forming a number of carbon nanotubes comprises:
depositing a catalyst within each of the vias; and
growing the number of carbon nanotubes in each via from the catalyst.

5. The method of claim 1, further comprising planarizing the first side of the substrate and the number of carbon nanotubes in each of the vias.

6. The method of claim 1, further comprising depositing a matrix material within each of the vias and around the carbon nanotubes in each via.

7. The method of claim 1, further comprising depositing a capping layer over the substrate first side and the number of carbon nanotubes.

8. The method of claim 1, wherein the circuitry is formed on the second side of the substrate prior to formation of the vias and the carbon nanotubes.

9. The method of claim 8, further comprising thinning the substrate at the first side prior to formation of the vias and the carbon nanotubes.

10. A method comprising:
forming a number of vias in a first side of a substrate;
forming a number of carbon nanotubes within each of the vias; and
attaching one side of a device layer to the first side of the substrate or to a second opposing side of the substrate.

11. The method of claim 10, further comprising forming circuitry on an opposing side of the device layer.

12. The method of claim 11, wherein the circuitry is formed on the opposing side of the device layer prior to attachment of the device layer to the substrate.

13. The method of claim 11, wherein the substrate and device layer comprise a wafer that is to be cut into a number of die, each die including some of the circuitry.

14. The method of claim 13, further comprising:
cutting the wafer into the number of die; and
attaching a thermal component to at least one of the die, the thermal component attached to a side of the die opposing the device layer.

15. The method of claim 10, wherein forming a number of carbon nanotubes comprises:
depositing a catalyst within each of the vias; and
growing the number of carbon nanotubes in each via from the catalyst.

16. The method of claim 10, further comprising planarizing the first side of the substrate and the number of carbon nanotubes in each of the vias.

17. The method of claim 10, further comprising depositing a matrix material within each of the vias and around the carbon nanotubes in each via.

18. The method of claim 10, further comprising depositing a capping layer over the substrate first side and the number of carbon nanotubes.

19. A device comprising:
a semiconductor die having a first side and an opposing second side;
a number of vias, each via extending from the first side down to a base;
a number of carbon nanotubes disposed within each of the vias, the carbon nanotubes in each via extending from the base of the via to approximately the first die side; and
a number of circuit elements disposed on the second side of the die.

20. The device of claim 19, wherein at least one of the circuit elements at least partially overlies a location of one of the vias.

21. The device of claim 19, further comprising a thermal component attached to the first side of the die.

22. The device of claim 19, wherein the carbon nanotubes within each via are approximately parallel to a wall of the via and approximately perpendicular to the first die side.

23. A device comprising:
a semiconductor die having a first side and an opposing second side;
a number of vias, each via extending from the first side down to a base;
a number of carbon nanotubes disposed within each of the vias, the carbon nanotubes in each via extending from the base of the via to approximately the first die side; and
a device layer attached to first side of the die or the second side of the die, the device layer including a number of circuit elements.

24. The device of claim 23, wherein at least one of the circuit elements at least partially overlies a location of one of the vias.

25. The device of claim 23, further comprising a thermal component attached to a side of the die opposing the device layer.

26. The device of claim 23, wherein the carbon nanotubes within each via are approximately parallel to a wall of the via and approximately perpendicular to the first side of the die.

27. A system comprising:
a memory; and
a processor coupled with the memory, the processor including
a die having a first side and an opposing second side;
a number of vias, each via extending from the first side down to a base;
a number of carbon nanotubes disposed within each of the vias, the carbon nanotubes in each via extending from the base of the via to approximately the first die side; and
a number of circuit elements disposed on the second side of the die.

28. The system of claim 27, wherein at least one of the circuit elements at least partially overlies a location of one of the vias.

29. The system of claim 27, further comprising a thermal component attached to the first side of the die.

30. A system comprising:
a memory; and
a processor coupled with the memory, the processor including
a die having a first side and an opposing second side;
a number of vias, each via extending from the first side down to a base;
a number of carbon nanotubes disposed within each of the vias, the carbon nanotubes in each via extending from the base of the via to approximately the first die side; and
a device layer attached to first side of the die or the second side of the die, the device layer including a number of circuit elements.

31. The system of claim 30, wherein at least one of the circuit elements at least partially overlies a location of one of the vias.

32. The system of claim 30, further comprising a thermal component attached to a side of the die opposing the device layer.
